(19) United States
(12) Patent Application Publication
(10) Pub. No.: US 2025/0311243 A1
(43) Pub. Date: Oct. 2, 2025

(54) THREE-DIMENSIONAL STACKED SEMICONDUCTOR DEVICES

(71) Applicant: Yangtze Memory Technologies Co., Ltd., Wuhan (CN)

(72) Inventors: Xiaoxin LIU, Wuhan (CN); Zongliang HUO, Wuhan (CN)

(21) Appl. No.: 18/769,342

(22) Filed: Jul. 10, 2024

(30) Foreign Application Priority Data
Apr. 2, 2024 (CN) 202410396443.0

(51) Int. Cl. H10B 80/00; H01L 23/00; H01L 25/00; H01L 25/065; H10B 41/27; H10B 43/27

(52) U.S. Cl. CPC H10B 80/00; H01L 24/08; H01L 24/80; H01L 25/0657; H01L 25/50; H10B 41/27; H10B 43/27; H01L 2224/08145; H01L 2224/80895; H01L 2224/80896; H01L 2924/14511

(57) ABSTRACT

Systems, devices, and methods for a semiconductor device are provided. In one aspect, a semiconductor device includes a first semiconductor structure. The first semiconductor structure includes a plurality of first channel structures extending along a first direction and a plurality of connecting structures. Each connecting structure includes a first region of a first conductive type, a second region of a second conductive type, and a third region of the first conductive type. A first end of a first channel structure is in contact with the first region of a corresponding connecting structure. The semiconductor device further includes a second semiconductor structure, which includes a plurality of second channel structures extending along the first direction. The first semiconductor structure and the second semiconductor structure are bonded along the first direction. The corresponding connecting structure is coupled to a first end of a corresponding second channel structure.

### CROSS-REFERENCE TO RELATED APPLICATIONS

This application claims priority to Chinese Patent Application No. 202410396443.0, filed on Apr. 2, 2024, which is hereby incorporated by reference in its entirety.

### TECHNICAL FIELD

The present disclosure relates to semiconductor devices and fabrication processes for semiconductor devices.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array. The memory cells can include vertical structures.

### SUMMARY

The present disclosure describes methods, devices, systems and techniques for forming a three-dimensional (3D) stacked semiconductor devices.

One aspect of the present disclosure features a semiconductor device, including: a semiconductor device includes a first semiconductor structure. The first semiconductor structure includes a plurality of first channel structures extending along a first direction and a plurality of connecting structures. Each connecting structure includes a first region of a first conductive type, a second region of a second conductive type, and a third region of the first conductive type. A first end of a first channel structure is in contact with the first region of a corresponding connecting structure. The semiconductor device further includes a second semiconductor structure, which includes a plurality of second channel structures extending along the first direction. The first semiconductor structure and the second semiconductor structure are bonded along the first direction. The corresponding connecting structure is coupled to a first end of a corresponding second channel structure.

In some implementations, the first conductive type is N conductive type, and the second conductive type is P conductive type.

In some implementations, the first semiconductor structure includes a first conductive line coupled to a second end of the first channel structure. The second end of the first channel structure is opposite to the first end of the first channel structure along the first direction. The second semiconductor structure includes a second conductive line coupled to a second end of the corresponding second channel structure. The first end of the corresponding second channel structure is opposite to the second end of the corresponding second channel structure along the first direction.

In some implementations, the first semiconductor structure further includes a plurality of conductive structure. A conductive structure of the plurality of conductive structures is in contact with the first region or the third region of the corresponding connecting structure.

In some implementations, the second semiconductor structure includes a plurality of conductive contacts isolated by a dielectric material. A first end of a conductive contact of the plurality of conductive contacts is coupled to the third region of the corresponding connecting structure. A second end of the conductive contact of the plurality of conductive contacts is coupled to the corresponding second channel structure of the plurality of second channel structures. The first end is opposite to the second end along the first direction.

In some implementations, the second region of the corresponding connecting structure is connected to a conductive line. A thickness of the second region of the corresponding connecting structure is equal to or larger than a thickness of the conductive line.

In some implementations, the thickness of the second region is a dimension of the second region along the first direction. The thickness of the conductive line is a dimension of the conductive line along the first direction.

In some implementations, each of the plurality of second channel structures includes a channel plug.

Another aspect of the present disclosure features a semiconductor device including a first semiconductor structure including a plurality of first channel structures extending along a first direction and a plurality of connecting structures. Each of the plurality of connecting structures includes a first region of a first conductive type and a second region of a second conductive type, a first end of a first channel structure of the plurality of first channel structures being in contact with the first region of a corresponding connecting structure of the plurality of connecting structures. A second semiconductor structure includes a plurality of second channel structures extending along the first direction. Each of the plurality of second channel structures includes a channel plug in a first end of the second channel structure. The channel plug includes a third region of the first conductive type. The first semiconductor structure and the second semiconductor structure are bonded along the first direction. The corresponding connecting structure is coupled to a channel plug of a corresponding second channel structure of the plurality of second channel structures.

In some implementations, the first conductive type is N conductive type, and the second conductive type is P conductive type.

In some implementations, the first semiconductor structure includes a first conductive line coupled to a second end of the first channel structure. The first end of the first channel structure is opposite to the second end of the first channel structure along the first direction. The second semiconductor structure includes a second conductive line coupled to a second end of the corresponding second channel structure. The first end of the corresponding second channel structure is opposite to the second end of the corresponding second channel structure.

In some implementations, the first semiconductor structure further includes a plurality of conductive structures. A conductive structure of the plurality of conductive structures is in contact with the second region of the corresponding connecting structure.

In some implementations, the second semiconductor structure includes a plurality of conductive contacts isolated by a dielectric material. A first end of a conductive contact of the plurality of conductive contacts is coupled to the second region of the corresponding connecting structure. A second end of the conductive contact is coupled to the channel plug of the corresponding second channel structure. The first end is opposite to the second end along the first direction.

In some implementations, the second region of the corresponding connecting structure is connected to a conductive line. A thickness of the second region of the corresponding connecting structure is equal to or larger than a thickness of the conductive line.

In some implementations, the thickness of the second region is a dimension of the second region along the first direction. The thickness of the conductive line is a dimension of the conductive line along the first direction.

Another aspect of the present disclosure features a method including: a first semiconductor structure is provided. The first semiconductor structure includes a plurality of first channel structures extending along a first direction and a plurality of connecting structures. A first end of a first channel structure of the plurality of first channel structures is in contact with a corresponding connecting structure of the plurality of connecting structures. A second semiconductor structure is provided. The second semiconductor structure includes a plurality of second channel structures extending along the first direction. Each of the plurality of second channel structures includes a channel plug in a first end of the second channel structure. The first semiconductor structure and the second semiconductor structure are bonded together. The corresponding connecting structure is coupled to a channel plug of a corresponding second channel structure of the plurality of second channel structures.

In some implementations, the corresponding connecting structure includes a first region of a first conductive type and a second region of a second conductive type. The channel plug of the corresponding second channel structure includes a third region of the first conductive type.

In some implementations, the corresponding connecting structure includes a first region of a first conductive type, a second region of a second conductive type, and a third region of the first conductive type.

In some implementations, the first conductive type is N conductive type, and the second conductive type is P conductive type.

In some implementations, the method further includes forming a plurality of conductive contacts on the second semiconductor structure. A first end of a conductive contact of the plurality of conductive contacts is coupled to the corresponding connecting structure of the plurality of connecting structures. A second end of the conductive contact of the plurality of conductive contacts is coupled to the channel plug of the corresponding second channel structure of the plurality of second channel structures. The first end is opposite to the second end along the first direction.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a cross-section of an example semiconductor device.

FIGS. 2A-2J illustrate cross-section views of example structures of an example semiconductor device at various stages of a fabrication process.

FIG. 3 illustrates a cross-section view of an example semiconductor device.

FIG. 4A illustrates a cross-section view of an example semiconductor device with semiconductor plugs.

FIG. 4B illustrates a cross-section view of an example semiconductor device with a substrate layer.

FIG. 5 illustrates a flow chart of an example process to form an example semiconductor device.

FIG. 6 illustrates a block diagram of a system.

It is to be understood that the various exemplary implementations shown in the figures are merely illustrative representations and are not necessarily drawn to scale.

### DETAILED DESCRIPTION

In some 3D memory devices, such as 3D NAND memory devices, a stack of gate electrodes may be arranged over a substrate, with a plurality of semiconductor channels through and intersecting word lines, into the implanted substrate. In this configuration, memory strings consisting of memory cells are positioned on top of each other, enabling increased storage density and capacity within the same chip footprint. This configuration allows for more efficient utilization of space and can lead to higher memory capacities in NAND flash storage devices.

This disclosure describes a semiconductor device and a method to form such semiconductor device. A semiconductor device includes a first semiconductor structure. The first semiconductor structure includes a plurality of first channel structures extending along a first direction and a plurality of connecting structures. Each of the plurality of connecting structures includes a first region of a first conductive type, a second region of a second conductive type, and a third region of the first conductive type. A first end of a first channel structure of the plurality of first channel structures is in contact with the first region of a corresponding connecting structure of the plurality of connecting structures. The semiconductor device further includes a second semiconductor structure, which includes a plurality of second channel structures extending along the first direction. The first semiconductor structure and the second semiconductor structure are bonded along the first direction. The corresponding connecting structure is coupled to a first end of a corresponding second channel structure of the plurality of second channel structures.

Implementations of the present disclosure can provide one or more of the following technical advantages. Firstly, a 3D memory device can include two or more semiconductor structures which are stacked with each other along a vertical direction, e.g., along a longitude axis of the channel structures. This stacked structure further increases storage density and capacity within the same chip footprint. In addition, stacked semiconductor devices ease the process complexity for forming channels with high aspect ratio, particularly in etching and deposition steps where uniformity and precision are crucial. Furthermore, by employing a connecting structure, e.g., an NPN amplifier, between adjacent two stack structures, a more uniform channel current can be achieved. This addresses the issue of degraded channel current in a multi-stacked 3D memory device. Channel current degradation can occur due to various factors, e.g., increased resistance in the channel structures, limited carrier mobility, and increased series resistance in the stacked layers. In some cases, the channel current of a lower stack, e.g., a stack farther away from the bit line, is lower than that of an upper stack, leading to performance degradation, slower read/write operations, and potential reliability issues. Uniform channel current distribution in 3D NAND flash memory can enhance reliability and longevity of the memory cells. With these techniques, a 3D NAND memory device with over 1000 layers can be achieved without comprising the channel current in the lower stack.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

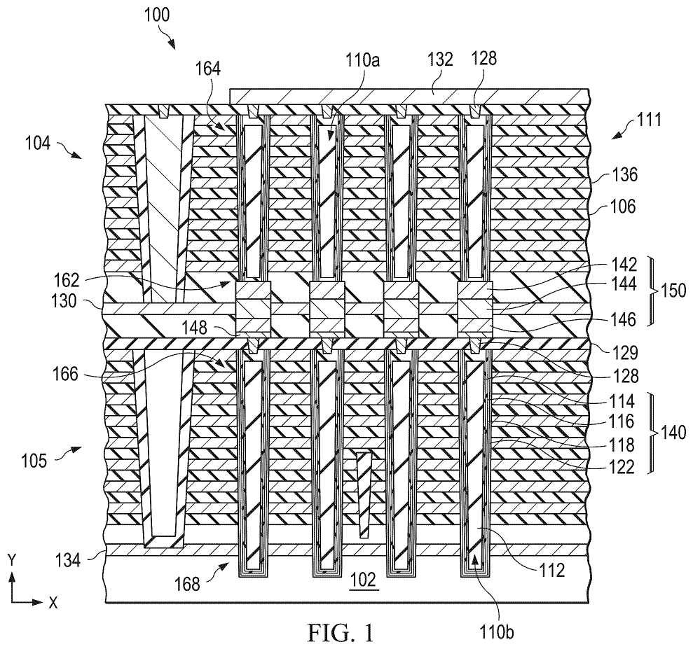

FIG. 1 illustrates a cross-section of an example 3D memory device 100. 3D memory device 100 may include a substrate 102, which is a doped semiconductor layer and may include silicon (e.g., single crystalline silicon), silicon germanium (SiGe), gallium arsenide (GaAs), germanium (Ge), silicon on insulator (SOI), germanium on insulator (GOI), or any other suitable materials. In some implementations, substrate 102 is a thinned substrate (e.g., a semiconductor layer), which was thinned by grinding, etching, chemical mechanical polishing (CMP), or any combination thereof. Substrate 102 of 3D memory device 100 includes two surfaces (e.g., a top surface and a bottom surface) extending laterally in the x-direction (i.e., the lateral direction). As used herein, whether one component (e.g., a layer or a device) is “on,” “above,” or “below” another component (e.g., a layer or a device) of a 3D memory device (e.g., 3D memory device 100) is determined relative to the substrate of the 3D memory device (e.g., substrate 102) in the y-direction (i.e., the vertical direction) when the substrate is positioned in the lowest plane of the 3D memory device in the y-direction.

In some implementations, 3D memory device 100 is a NAND Flash memory device in which memory cells are provided in the form of an array of NAND memory strings each extending vertically above substrate 102.

As shown in FIG. 1, 3D memory device 100 may include two semiconductor structures, 104 and 105, which are bonded together. Each semiconductor structure includes a stack structure 111. The bonding of the two semiconductor structures 104 and 105 can involve hybrid bonding. A hybrid bonding can include a combination of metal-to-metal bonding and a direct oxide bonding, as described with further details below. Each stack structure 111 has interleaved gate lines 136 and first dielectric layer 106. The gate lines 136 may include conductive materials including, but not limited to, tungsten (W), cobalt (Co), copper (Cu), aluminum (Al), polysilicon, doped silicon, silicides, or any combination thereof. First dielectric layers 106 may include dielectric materials including, but not limited to, silicon oxide, silicon nitride, silicon oxynitride, or any combination thereof. In some implementations, each stack structure 111 has 200-600 layers.

The NAND memory string may include one or more channel structures extending vertically through each of the semiconductor structures in the Y-direction. The first semiconductor structure 104 includes the first channel structures 110a, and the second semiconductor structure 105 includes the second channel structure 110b. The first channel structures 110a and the second channel structures 110b can collectively be referred as channel structures 110 in this disclosure. Channel structures 110 may include a channel hole or a channel trench with a layered structure 140 on the sidewalls. In some implementations, the remaining space of channel structures 110 may be partially or fully filled with a filling layer 112 including dielectric materials, such as silicon oxide.

In some implementations, the layered structure 140 comprises a blocking layer, a charge trapping layer (also called storage layer in some cases), a dielectric layer (also called a tunneling layer in some cases), and a semiconductor channel layer. The semiconductor channel layer 114 is in contact with and laterally surrounded by the dielectric layer 116. The dielectric layer 116 is in contact with and laterally surrounded by the charge trapping layer 118. The charge trapping layer 118 is in contact with and laterally surrounded by the blocking layer 122. In other words, filling layer 112, semiconductor channel layer 114, dielectric layer 116, charge trapping layer 118, and blocking layer 122 are arranged radially from the center toward the outer surface of the channel trench in this order. Dielectric layer 116 may include silicon oxide, silicon oxynitride, or any combination thereof. Charge trapping layer 118 may include silicon nitride, silicon oxynitride, silicon, or any combination thereof. Blocking layer 122 may include silicon oxide, silicon oxynitride, high dielectric constant (high-k) dielectrics, or any combination thereof. The semiconductor channel layer 114 may include doped polysilicon, silicon germanium (SiGe), III-V materials (e.g., gallium arsenide GaAs), or any combination thereof. In one example, the layered structure 140 comprises silicon oxide/silicon oxynitride (or silicon nitride)/silicon oxide/polysilicon (ONOP), for the blocking layer 122, the charge trapping layer, 118 the dielectric layer 116, and the semiconductor channel layer 114, respectively.

The first stack structure 111, e.g., the stack structure in the first semiconductor structure 104, includes a connecting structure 150 at the first end 162 of the first channel structure 110a. The connecting structure 150 includes three regions: a first region 142 of a first conductive type, a second region 144 of a second conductive type, and a third region 146 of the first conductive type. The first region 142 is in contact with the second region 144 and the first end 162 of the first channel structure 110a on its opposite sides. The second region 144 is in contact with the third region 146. In some implementations, the first conductive type is N conductive type, and the second conductive type is P conductive type. Therefore, the connecting structure 150 has a NPN bipolar junction structure. In some implementations, the first conductive type is P conductive type, and the second conductive type is N conductive type. Therefore, the connecting structure 150 has a PNP bipolar junction structure. N type dopants can include Phosphorus (P) or Arsenic (As), and P-type dopants can include Boron (B) or Gallium (Ga) at a desired doping level. Although FIG. 1 illustrates that all three regions are vertically stacked together and have similar lateral dimension along the X direction, it is understood that the connecting structure 150 can have various suitable layout and/or dimensions. For example, the connecting structure 150 can have a lateral NPN or PNP layout where three regions are arranged laterally along X direction.

In some implementations, the first semiconductor structure 104 includes multiple conductive structures 148. A conductive structure 148 can be in contact with the first region 142 or the third region 146 of the corresponding connecting structure 150. As illustrated in FIG. 1, the conductive structure 148 is in contact with the third region 146 of the connecting structure 150. In some implementations, the conductive structure 148 includes titanium silicide to reduce the ohmic resistance between the connecting structure 150 and the second channel structure 110b. The conductive structures 148 can be formed by depositing a titanium layer on the connecting structure 150 followed by an annealing process to transforms the titanium into titanium silicide.

Channel structures 110 in each semiconductor structure 104, 105 are coupled together through the connecting structure 150. In some implementations, the second semiconductor structure 105 includes conductive contacts 128 isolated by a dielectric material 129. A first end of a conductive contact 128 is coupled to the third region 146 of the corresponding connecting structure 150. A second end of the conductive contact 128 is coupled to the corresponding second channel structure 110b. The first end is opposite to the second end along the Y direction. In some implementations, the first end of the conductive contact 128 is in contact with the conductive structure 148 as illustrated in FIG. 1. The conductive contacts 128 can comprise conductive materials including, but not limited to, tungsten (W), cobalt (Co), copper (Cu), aluminum (Al), polysilicon, doped silicon, silicides, or any combination thereof.

In some implementations, the second region 144 of the connecting structure 150 is connected to a conductive line 130, as illustrated in FIG. 1. In some implementations, the material of the conductive line 130 includes, but not limited to W, Co, Cu, Al, TiN, TaN, polysilicon, silicide, or any combination thereof. In some implementations, the first region 142 is a collector region of a bipolar junction, the second region 144 is a base region, and the third region 146 is an emitter region. The conductive line 130 can be used to control the flow of current between the first region 142 (e.g., collector) and the third region 146 (e.g., emitter). Control can be achieved through the modulation of the conductivity of the second region 144 (e.g., base). Without limiting to any particular theory, when a current is applied to the second region 144 (e.g., base), the current I_{E} flowing through the third region 146 (e.g., emitter) can be equal to the sum of the current I_{C} flowing through the first region 142 (e.g., collector) and the current I_{B} flowing through the second region 144 (e.g., base). In other words, I_{E}=I_{B}+I_{C}. Within this context, as the first region 142 (e.g., collector) is connected to the first channel structure 110a, the current flows through the first channel structure 110a can be equal to or substantially similar to I_{C}. Likewise, as the third region 146 (e.g., emitter) is connected to the second channel structure 110b, the current flows through the second channel structure 110b can be equal to or substantially similar to I_{E}. Since I_{E}=I_{B}+I_{C}, the current flowing through the second channel structure 110b is larger than or substantially similar to the current flowing through the first channel structure 110a. Therefore, the current is enhanced in the second channel structure 110b.

In some implementations, the thickness of the second region 144 is equal to or larger than a thickness of the conductive line 130. The thickness can be a dimension along Y direction. In some implementations, the second region 144 is at least 50 nm thicker than the conductive line 130. In some implementations, the thickness of the second region 144 is between 100 nm and 350 nm, and the thickness for the conductive line 130 is between 50 nm and 300 nm. Thicker second region 144 can reduce interference or leakage between the conductive line 130 and other two regions.

Channel structures 110 in each semiconductor structure 104, 105 can have a cylinder shape (e.g., a pillar shape), as illustrate in FIG. 1. In some implementations, channel structure 110 in each stack structure 111 may be formed by stacking more than one cylinder structure. It is understood that the channel structure 110 in each stack structure 111 may have other shapes (e.g., elliptical cylinder or irregular shape).

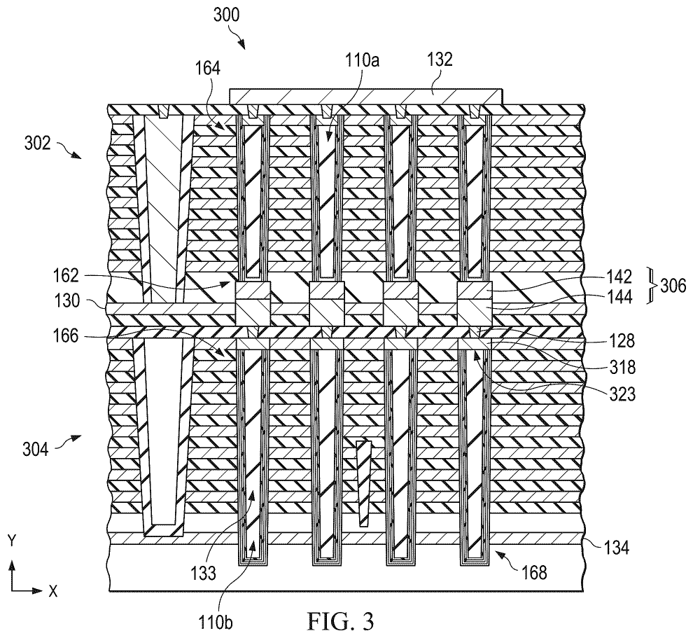

In some implementations, each of the second channel structures 110b includes a channel plug (not shown in FIG. 1). The channel plug can be in an upper portion (e.g., at the upper end) of channel structure 110 and stacked over the layered structure 140. Channel plug may be in contact with the upper end of semiconductor channel layer 114 of the layered structure 140. In some implementations, the channel plug material can include, but not limited to, TiN, TaN, Al, W, Cu, doped-polysilicon, silicides, or any combination thereof. In some implementations, channel plugs are implanted with desired dopants to form the first region 142 or the third region 146 of the connecting structure 150, as described with further details in FIG. 3.

In some implementations, the first semiconductor structure 104 includes a first conductive line 132 coupled to a second end 164 of the first channel structure 110a. The second end 164 of the first channel structure 110a is opposite to the first end 162 of the first channel structure 110a along the Y direction. The second semiconductor structure 105 includes a second conductive line 134 coupled to a second end 168 of the corresponding second channel structure 110b. The first end 166 of the corresponding second channel structure 110b is opposite to the second end 168 of the corresponding second channel structure 110b along the first direction, e.g., the Y direction. In some implementations, the first conductive line 132 is a bit line which is connected to drain terminals of the first channel structure 110a. Within this context, the first region 142 of the connecting structure 150 can be a N collector region. Thus, the bit line, e.g., the first conductive line 132, is electrically coupled to the collector of the connecting structures 150. In some implementations, the second conductive line 134 is a source line connected to source terminals of the second channel structure 110b. Within this context, the third region 146 can be a N emitter region. Thus, the source line is electrically coupled to the emitter of the connecting structures 150. In some implementations, the material of the first conductive line 132 and the second conductive line 134 includes, but not limited to W, Co, Cu, Al, TiN, TaN, polysilicon, silicide, or any combination thereof.

In some implementations, second channel structure 110b may further include a channel contact, or called semiconductor plug, in a lower portion (e.g., at the lower end) of second channel structure 110b (not shown). As used herein, the “upper end” of a component (e.g., second channel structure 110b) is the end farther away from substrate 102 in the positive y-direction, and the “lower end” of the component (e.g., channel structure 110b) is the end closer to substrate 102 in the negative y-direction. The semiconductor plug may include a semiconductor material, such as silicon, which is epitaxially grown from substrate 102 in any suitable directions. It is understood that in some implementations, the semiconductor plug includes single crystalline silicon, the same material as substrate 102. In other words, the semiconductor plug may include an epitaxially-grown semiconductor layer that is the same as the material of substrate 102. In some implementations, part of the semiconductor plug is above the top surface of substrate 102 and in contact with the semiconductor channel layer 114 of the second channel structures 110b. The semiconductor plug may function as a channel controlled by a source select gate controlled by the NAND memory string.

In some implementations, each gate line 136 in stack structure 111 (e.g., a memory stack) functions as a gate conductor of memory cells in the NAND memory string. Gate lines 136 may extend laterally coupling a plurality of memory cells. In some implementations, memory cell transistors in NAND memory string include semiconductor channel layer 114, memory film (including dielectric layer 116, charge trapping layer 118, and blocking layer 122), and the gate lines 136. The gate lines 136 may further include a gate conductor made from tungsten, adhesion layers including titanium/titanium nitride (Ti/TiN) or tantalum/tantalum nitride (Ta/TaN), and gate dielectric layers made from high-k dielectric materials.

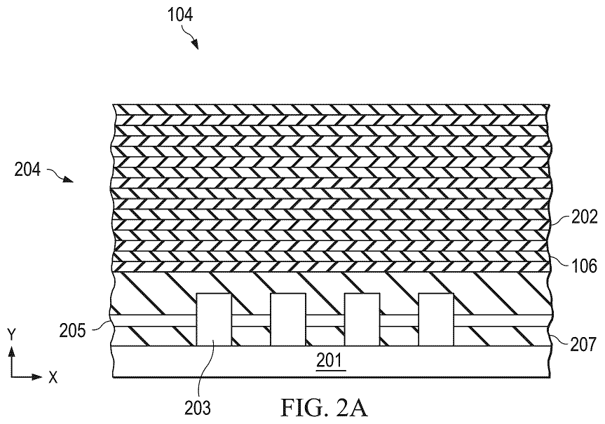

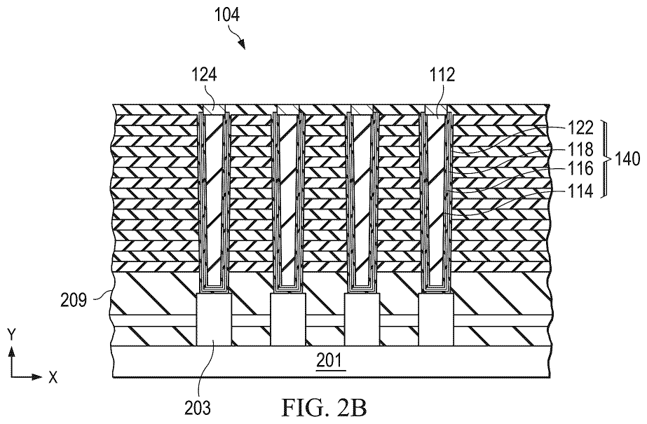

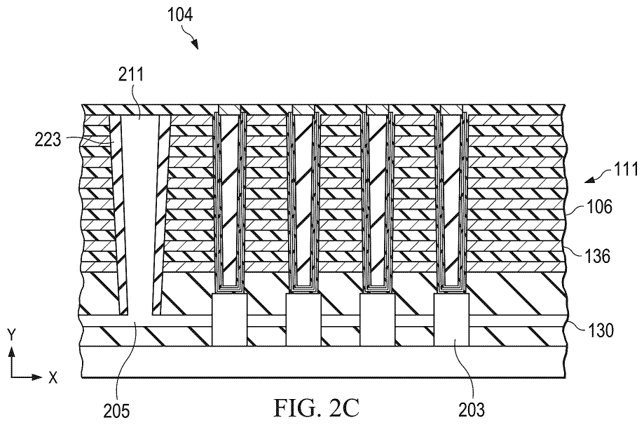

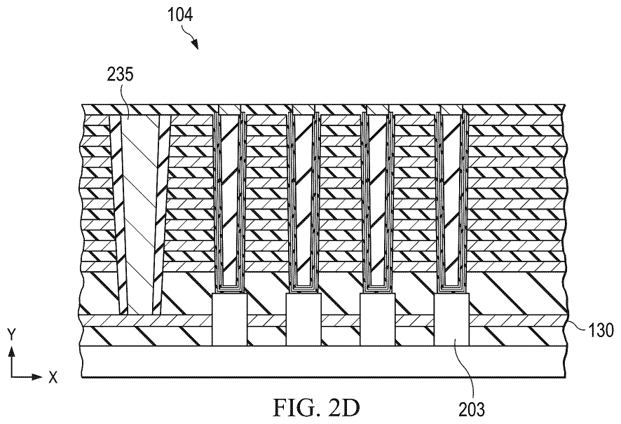

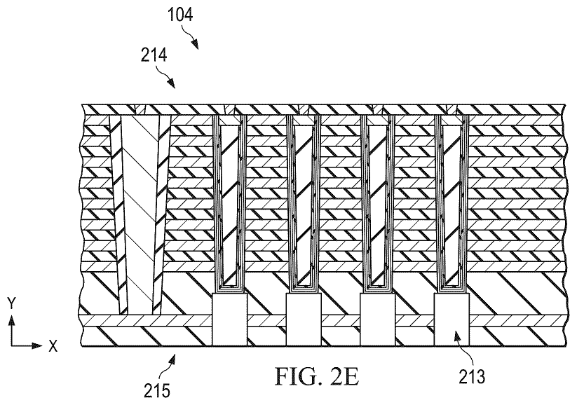

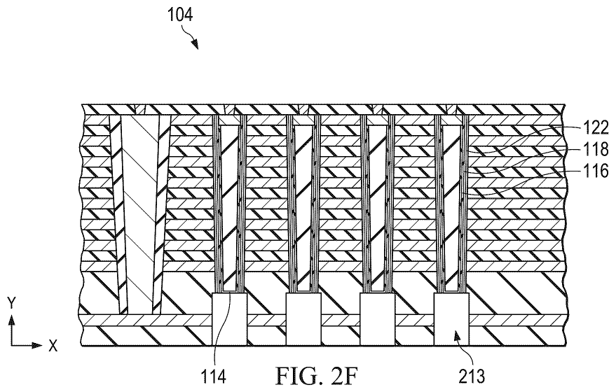

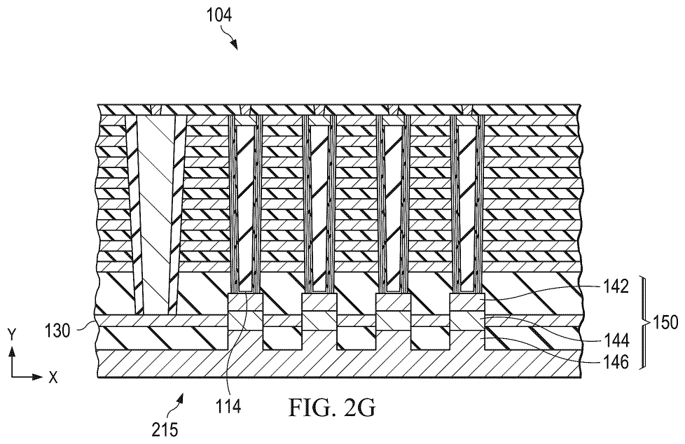

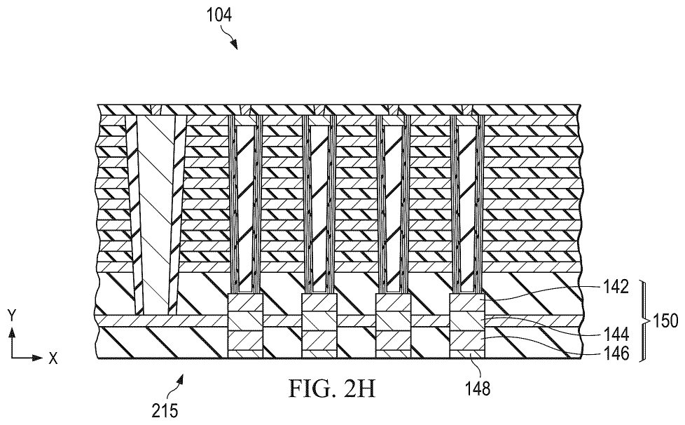

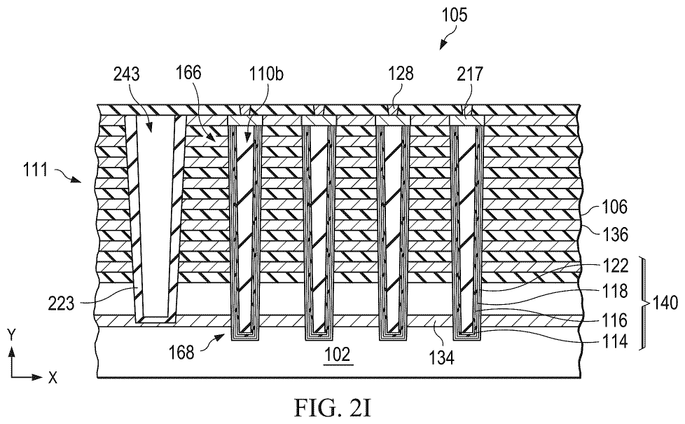

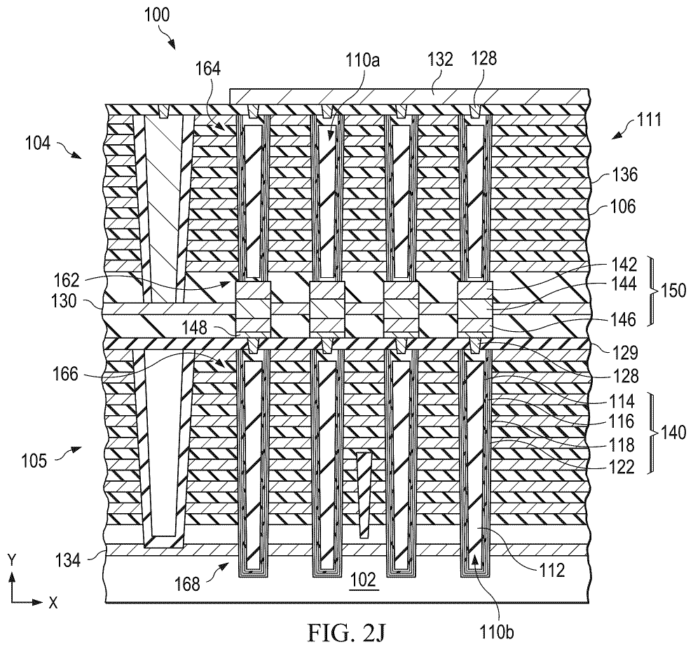

FIGS. 2A-2J illustrate cross-section views of example structures of an example semiconductor device 100 at various stages of a fabrication process. In particular, FIGS. 2A-2H illustrates cross-section views of example structures of an example first semiconductor structure 104 at various stages of a fabrication process. FIG. 2I illustrates a cross-section view of an example second semiconductor structure 105. FIG. 2J illustrates a cross-section view of an example semiconductor device 100, which is identical to FIG. 1.

As illustrated in FIG. 2A, an interleaved structure 204 is formed on a substrate 201 which includes interleaved sacrificial layer 202 and insulating layer, e.g., first dielectric layer 106. The sacrificial layer 202 can be configured to be replaced with a conductive material to form gate lines 136 at a later stage of the process as described below in FIG. 2C. First dielectric layers 106 may comprise dielectric materials including, but not limited to, silicon oxide, silicon nitride, silicon oxynitride, or any combination thereof. Sacrificial layers 202 may also include dielectric materials including, but not limited to, silicon oxide, silicon nitride, silicon oxynitride, or any combination thereof. Sacrificial layer 202 can comprise a different material than the first dielectric layer 106 such that it can be selectively removed and replaced with a conductive material at a later processing stage. For example, the sacrificial layer includes silicon nitride, while the first dielectric layer includes silicon oxide.

The first semiconductor structure 104 can include sacrificial semiconductor plugs 203 in a lower portion (e.g., at the lower end) of first channel structure 110a. As used herein, the “upper end” of a component (e.g., the first channel structure 110a) is the end farther away from substrate 201 in the positive y-direction, and the “lower end” of the component (e.g., the first channel structure 110a) is the end closer to substrate 201 in the negative y-direction. In some implementations, the sacrificial semiconductor plugs 203 includes single crystalline silicon, which is epitaxially grown on or from substrate 201 in any suitable directions. In some implementations, the semiconductor plug includes polysilicon. Part of the sacrificial semiconductor plugs 203 can be above the top surface of substrate 201, as shown. The semiconductor plug can have a same or substantial similar distribution density or pitch as the first channel structures 110a such that at a later stage, e.g., as illustrated in FIG. 2B, a first channel structure 110a is formed above each respective sacrificial semiconductor plug 203.

In some implementations, a connection line 205 is connected to each of the sacrificial semiconductor plugs 203. The connection line 205 extends along the X direction and is isolated from the substrate 201 with a dielectric layer 207. The connection line 205 can include sacrificial polysilicon but with dopants differing from those used in the sacrificial semiconductor plug 203. The sacrificial polysilicon in the connection line 205 can be later replaced with a conductive material to form the conductive line 130 (see FIG. 1) for controlling the connecting structure 150 at a later stage, as described with further details in FIG. 2C.

As illustrated in FIG. 2B, first channel structures 110a are formed which extend through the interleaved structure 204 along Y direction. In some implementations, the first channel structures 110a have a cylinder shape. Because of etching process, the cylinder may have a larger top opening compared to the bottom opening, as shown. In some implementations, first channel structures 110a may be formed by stacking more than one cylinders in the first semiconductor structure 104.

The first channel structures 110a can include a layered structure 140 on sidewalls. As noted above, the layered structure 140 can include a blocking layer 122, a charge trapping layer 118 (also called storage layer in some cases), a dielectric layer 116 (also called a tunneling layer in some cases), and a semiconductor channel layer 114. The semiconductor channel layer 114, the dielectric layer 116, the charge trapping layer 118, and the blocking layer 122 are arranged radially from the center toward the outer surface of the first channel structures 110a in this order. This arrangement can be achieved by depositing theses layers sequentially on sidewalls in reverse order. In some implementations, the layered structure 140 includes silicon oxide/silicon oxynitride (or silicon nitride)/silicon oxide/polysilicon (ONOP), for the blocking layer 122, the charge trapping layer, 118 the dielectric layer 116, and the semiconductor channel layer 114, respectively. The layered structure 140 can be deposited using one or more thin film deposition processes, including, but not limited to, chemical vapor deposition (CVD), physical vapor deposition (PVD), atomic layer deposition (ALD), sputtering, or any combination thereof. In some implementations, an implantation process is performed to dope the polysilicon for the semiconductor channel layer 114. The first channel structures 110a further include a filling layer 112 in the center. The filling layer 112 can be a dielectric material, including but not limited to, silicon oxide, silicon nitride, silicon oxynitride, or any combination thereof.

The first channel structures 110a can be formed by etching channel trenches first and then filled with the layered structure 140 and the filling layer 112 inside the channel trenches. In some implementations, the etching for channel trenches is stopped above the sacrificial semiconductor plugs 203. The first channel structures 110a can be separated from the sacrificial semiconductor plugs 203 by the dielectric layer 209. The dielectric layer 209 can include the same material as the first dielectric layers 106.

In some implementations, a channel plug 124 can be formed on the upper portion of each first channel structure 110a. The channel plug 124 can be made of materials including, but not limited to, TiN, TaN, Al, W, Cu, doped-polysilicon, silicides, or any combination thereof. The channel plug 124 can have a greater lateral dimension, e.g., X dimension or Z dimension, than the semiconductor channel layer 114. In some implementations, the channel plug 124 can be first filled with an insulating material. More specifically, an insulating material can be first used to form the channel plug 124. The insulating material of the channel plug 124 can be replaced with a conductive material in a later process stage. To replace the insulating materials with the conductive material, the insulating material can be partially or fully removed by dry etching or wet etching. The conductive material is then filled into the vacancies after etch.

As illustrated in FIG. 2C, a first connection trench 211 is formed which extends through the stack structure 111 along the Y direction and lands on the connection line 205. The etching process can involve one or more dry etching and/or wet etching process, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H2SO4/H2O2), or any combination thereof.

The sacrificial layers 202 are replaced with a conductive material to form gate lines 136. The gate lines 136 are isolated from one another by the first dielectric layers 106. In some implementations, sacrificial layers 202 may be removed by a wet etch and/or dry etch process. After the removal of sacrificial layers 202, a plurality of openings may be formed between adjacent first dielectric layers 106. Then, a conductive material is deposited into the openings to form gate lines 136. In some implementations, gate lines 136 may have conductive materials including, but not limited to, W, Co, Cu, Al, polysilicon, doped silicon, silicides, or any combination thereof. In some implementations, the gate lines 136 may be formed by one or more thin film deposition processes including, but not limited to, CVD, PVD, ALD, MOCVD, MBE, sputtering, or any combination thereof.

A spacer 223 is deposited on inner surfaces of the first connection trench 211. The spacer 223 can protect the stack structure 111 during a subsequent etching process. The spacer 223 can be formed with dielectric materials including, but not limited to, silicon oxide, silicon nitride, silicon oxynitride, low-k dielectrics, or any combination thereof.

Another etching is performed to punch through the spacer 223 on the bottoms of the first connection trench 211, exposing the connection line 205 underneath. The materials of the connection line 205, e.g., sacrificial polysilicon, are then removed and thus an opening line is formed, as illustrated in FIG. 2C. As noted above, the connection line 205 can have either different materials or same material (e.g., polysilicon) but with different dopants compared to the sacrificial semiconductor plugs 203. The etching process can be configured to selectively etch only the material of the connection line 205, leaving the material of the sacrificial semiconductor plugs 203 substantially intact. The etching process can involve one or more dry etching and/or wet etching process.

As illustrated in FIG. 2D, a conductive material is deposited into the openings of the connection line 205 to form the conductive line 130 and into the first connection trench 211 to form a first connection structure 235. As such, the conductive line 130 and the first connection structure 235 are electrically connected. The first connection structure 235 can be coupled to external circuitries or devices to control and manage the semiconductor device 100. In some implementations, the conductive material includes but not limited to W, Co, Cu, Al, TiN, TaN, polysilicon, or any combination thereof. The conductive material can be deposited by one or more thin film deposition processes including, but not limited to, CVD, PVD, ALD, Metal-Organic Chemical Vapor Deposition (MOCVD), sputtering, electroplating, electroless plating, electron-beam evaporation, or any combination thereof.

As illustrated in FIG. 2E, the sacrificial semiconductor plugs 203 are etched away, forming openings 213. This process stage can involve employment of a carrier wafer (not shown) and a substrate thinning process. The carrier wafer can be bonded with the first semiconductor structure 104 on the front side 214 of the first semiconductor structure 104. In some implementations, the bonding wafer is a CMOS wafer. The CMOS wafer can include CMOS circuitry built by transistors, capacitors, resistors, diodes, bipolar junctions, inductors, varactors, or a combination thereof. The combination of these components allows for the creation of complex digital and analog circuits for the memory array control. The bonding side of the carrier wafer can be cleaned and prepared to ensure proper adhesion with the first semiconductor structure 104. Once the carrier wafer is ready, the first semiconductor structure 104 is placed and bonded onto the bonding side of the carrier wafer. After bonding, the combined structure is flipped over to allows access to the back side 215 of the first semiconductor structure 104.

With the combined structure flipped, the silicon substrate is thinned or removed from the first semiconductor structure 104. This substrate thinning or removal process may utilize techniques such as grinding, mechanical thinning (e.g., grinding, polishing, and/or chemical mechanical polishing (CMP)), chemical thinning (e.g., wet etching, dry etching), laser thinning, acoustic thinning, or any combination thereof.

After the silicon substrate is removed or thinned, the sacrificial semiconductor plugs 203 are exposed. An etching process is subsequently performed to remove the exposed sacrificial semiconductor plugs 203 and form openings 213 in the same locations, as illustrated in FIG. 2E.

As illustrated in FIG. 2F, a further etching is performed to deepen each opening 213 and remove part of the layered structure 140 (e.g., the blocking layer 122, the charge trapping layer 118 and the dielectric layer 116) to expose the semiconductor channel layer 114. The etching process can involve one or more dry etching and/or wet etching process, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H2SO4/H2O2), or any combination thereof.

As illustrated in FIG. 2G, the connecting structures 150 are formed in the openings 213. As noted above, the connecting structures 150 can include three regions, a first region 142 of a first conductive type, a second region 144 of a second conductive type, and a third region 146 of the first conductive type. In some implementations, the first conductive type is N conductive type, and the second conductive type is P conductive type. In other words, connecting structures 150 can be NPN bipolar junctions with N collectors, P bases and N emitters. Within this context, in some implementations, the connecting structures 150 can be formed by firstly depositing a polysilicon with N-type dopants (e.g., Phosphorus (P) or Arsenic (As)) into the openings 213 to form the first region 142. The first region 142 is in contact with the semiconductor channel layer 114. Thus, the first channel structures 110a are electronically connected with the respective connecting structures 150. An etching back process can be involved to reduce the thickness (e.g., Y dimension) of the first region 142, thereby preventing its undesired contact with the conductive line 130. For the second region 144, SiGe can be deposited or grown in contact with the first region 142. P-type dopants (e.g., Boron (B) or Gallium (Ga)) can be implanted into the SiGe to form the second region 144, e.g., a P base. Similarly, etching back process can be deployed to control the thickness of the second region 144. Subsequently, an epitaxial silicon with N+ type dopants (e.g., Phosphorus (P) or Arsenic (As)) are grown in contact with the second region 144 to form the third region 146, e.g., a N emitter. As noted above, in some implementations, the second region 144 is at least 50 nm thicker than the conductive line. Thickness can be the dimension along Y direction. In some implementations, the thickness of the second region 144 is between 100 nm and 350 nm, and the thickness of the conductive line 130 is between 50 nm and 300 nm. Thicker second region 144 can reduce interference or leakage between the conductive line 130 and other two regions of the connecting structures 150.

Although FIG. 2G illustrates that all three regions of a connecting structure 150 are vertically stacked together along Y direction and have similar lateral dimension along the X direction, it is understood that the connecting structure 150 can have various suitable layout and/or dimension. For example, the connecting structure 150 can have a lateral NPN layout wherein three regions are arranged laterally along X direction.

As illustrated in FIG. 2H, a polishing process is performed to remove extra material, e.g., the extra material for the third region in FIG. 2G, on the back side 215 of the first semiconductor structure 104. Conductive structures 148 can be formed in contact with the connecting structures 150. More specifically, the conductive structures 148 can be in contact with the first region 142 or the third region 146 of the corresponding connecting structure 150. In some implementations, the conductive structure 148 includes titanium silicide to reduce the ohmic resistance between the connecting structure 150 and the second channel structure 110b. The conductive structures 148 can be formed by depositing a titanium layer in contact with the connecting structure 150 followed by an annealing process to transforms the titanium into titanium silicide.

FIG. 2I illustrates a cross-section view of an example second semiconductor structure 105. As shown, the second semiconductor includes a stack structure 111 with interleaved gate lines 136 and first dielectric layer 106. Multiple second channel structures 110b are formed extending through the stack structure 111 into the substrate 102 along the Y direction. Similar to the first channel structures 110a, each of the second channel structures 110b has a layered structure 140 including a blocking layer 122, a charge trapping layer 118 (also called storage layer in some cases), a dielectric layer 116 (also called a tunneling layer in some cases), and a semiconductor channel layer 114. The second channel structure 110b can have the same array layout (e.g., density, pitch, dimension) as the first channel structures 110a such that each first channel structure 110a can be stacked on a respective one of the second channel structures 110b (see FIG. 1).

The second semiconductor structure 105 can include conductive contacts 128 isolated by a dielectric material. The conductive contact 128 is coupled to a corresponding second channel structure 110b at the first end 166 of the second channel structure 110b. The conductive contacts 128 can comprise conductive materials including, but not limited to, tungsten (W), cobalt (Co), copper (Cu), aluminum (Al), polysilicon, doped silicon, silicides, or any combination thereof.

As shown, in some implementations, the second semiconductor structure 105 includes a second conductive line 134. The second conductive line 134 is coupled to a second end 168 of the corresponding second channel structure 110b. In some implementations, the second conductive line 134 is embedded in the substrate 102 as shown. In some implementations, the second conductive line 134 is a source line connected to source terminals of the second channel structure 110b. In some implementations, the material of the second conductive line 134 includes, but not limited to W, Co, Cu, Al, TiN, TaN, polysilicon, silicide, or any combination thereof.

The second semiconductor structure 105 can have a second connection structure 243 extending through the stack structure 111 along Y direction and lands on the second conductive line 134. The second connection structure 243 can be filled with polysilicon surrounded by a spacer 223. In some implementations, the second connection structure 243 is electrically isolated from the second conductive line 134 through the spacer 223. The spacer 223 can be made of dielectric material, including without limitation, silicon oxide, silicon nitride, silicon oxynitride, or any combination thereof. In some implementations, the second connection structure 243 is not electrically connected to another other structures. In other words, the second connection structure 243 is configured to be floating.

In some implementations, the second semiconductor structure 105 includes a channel plug 217. The channel plug 217 can be formed on the upper portion of each second channel structure 110b. The channel plug 217 can be made of materials including, but not limited to, TiN, TaN, Al, W, Cu, doped-polysilicon, silicides, or any combination thereof. The channel plug 127 can have a greater lateral dimension, e.g., X dimension or Z dimension, than that of the semiconductor channel layer 114.

FIG. 2J illustrates a cross-section view of an example integrated semiconductor device 100, which is identical to FIG. 1. The semiconductor device 100 is formed by bonding the first semiconductor structure 104 and the second semiconductor structure 105 together along the Y axis. The bonding process can involve hybrid bonding, including a combination of metal-to-metal bonding and a direct oxide bonding. For example, at the bonding interface 151, one end of the conductive contact 128 is connected to a respective one of the connecting structures 150 or the conductive structures 148 in the first semiconductor structure 104. The other end of the conductive contact 128 is connected to a respective one of the second channel structures 110b in the second semiconductor structure 105. Adjacent conductive contacts 128 are isolated by the dielectric layer 129.

After bonding, the first channel structures 110a and the corresponding second channel structures 110b are coupled together to form an integrated channel structure 133. One end of the integrated channel structure 133, e.g., the second end 164 of the first channel structures 110a, can be coupled to a bit line, e.g., the first conductive line 132. The opposite end of the integrated channel structure 133, e.g., the second end 168 of the second channel structures 110b, can be coupled to a source line, e.g., the second conductive line 134. One or more integrated channel structures 133 form a memory string.

As noted above in FIG. 1, the current in the second channel structures 110b can be substantially similar to or higher than that of the first channel structure 110a. This addresses the issue of degraded current in the channel structures in a multi-stacked 3D memory device. Current degradation can occur due to various factors such as increased resistance in the channel structures, limited carrier mobility, and increased series resistance in the stacked layers. When the current in the second channel structure 110b becomes significantly lower than that of the first channel structures 110a, it can lead to performance degradation, slower read/write operations, and potential reliability issues. Ensuring that the current in the second channel structures 110b is comparable to or higher than that of the first channel structures 110a helps maintain more uniform current distribution across the integrated channel structures 133. This further ensures consistent device performance and enhances reliability throughout the entire semiconductor memory device 100.

Although not shown, it is understood that the connecting structure 150, e.g., a NPN bipolar junction, can be formed on the first end 166 of the second channel structures 110b. It is further understood that three or more semiconductor structures can be bonded together in a similar manner to further increase memory density. The connecting structures 150 can be utilized between any adjacent two semiconductor structures to enhance the current flowing through the channel structures that are located further away from the bit line, e.g., the first conductive line 132.

FIG. 3 illustrates a cross-section view of another example semiconductor device 300. Instead of forming all three regions of the connecting structure within a single semiconductor structure, they can be fabricated on two separate semiconductor structures. As shown, the semiconductor device 300 includes a first semiconductor structure 302 and a second semiconductor structure 304. The first semiconductor structure 302 includes multiple first channel structures 110a extending along a first direction, e.g., Y direction, and multiple connecting structures 306. Each connecting structure 306 can include a first region 142 of a first conductive type and a second region 144 of a second conductive type. A first end of a first channel structure 110a is in contact with the first region 142 of a corresponding connecting structure 306, as illustrated.

The second semiconductor structure 105 can include multiple second channel structures 110b extending along the first direction, e.g., the Y direction. Each second channel structure 110b can include a channel plug 323 at a first end 166 of the second channel structure 110b. The channel plug 323 includes a third region 318 of the first conductive type.

As shown, the first semiconductor structure 302 and the second semiconductor structure 304 are bonded along the Y direction. Each connecting structure 306 is coupled to a channel plug 323 of a corresponding second channel structure 110b. Therefore, the combined structure has three regions: a first region 142 of a first conductive type, a second region 144 of a second conductive type, and a third region 318 of the first conductive type.

In some implementations, the first conductive type is N conductive type, and the second conductive type is P conductive type. In some implementations, the combined three regions form a NPN bipolar junction, e.g., the first region 142 is a N collector, the second region 144 is a P base, and the third region 318 is a N emitter. In some implementations, the combined three regions form a PNP bipolar junction, e.g., the first region 142 is a P collector, the second region 144 is a N base, and the third region 318 is a P emitter. In some implementations, the material of the first region 142 and/or the third region 318 include a doped polysilicon or single crystalline silicon. The dopants can be N+ type dopants (e.g., Phosphorus (P) or Arsenic (As)) or P-type dopants (e.g., Boron (B) or Gallium (Ga)) at a desired doping level. In some implementations, the material of the second region 144 includes SiGe.

In some implementations, the first semiconductor structure 302 includes a first conductive line 132, e.g., a bit line, coupled to second ends 164 of the first channel structures 110a. The first end 162 of the first channel structure 110a is opposite to the second end 164 of the first channel structure 110a along the first direction, e.g., the Y direction.

In some implementations, the second semiconductor structure 304 includes a second conductive line 134, e.g., a source line, coupled to second ends 168 of the second channel structures 110b. The first end 166 of the second channel structure 110b is opposite to the second end 168 of the second channel structure 110b along the first direction, e.g., the Y direction.

In some implementations, the first semiconductor structure 302 includes multiple conductive structures (not shown). Conductive structures are in contact with the second region 144 of the corresponding connecting structure 306. In some implementations, the conductive structure includes titanium silicide to reduce the ohmic resistance between the connecting structure 306 and the second channel structure 110b. The conductive structures can be formed by depositing a titanium layer in contact with the second region 144 of the connecting structure 306 followed by an annealing process to transforms the titanium into titanium silicide.

In some implementations, the second semiconductor structure 304 includes a plurality of conductive contacts 128 isolated by a dielectric material, as illustrated in FIG. 3. A first end of a conductive contact 128 is coupled to the second region 144 of the corresponding connecting structure 306. A second end of the conductive contact 128 is coupled to the channel plug 323 of the corresponding second channel structure 110b. The first end is opposite to the second end along the first direction, e.g., Y direction. In other words, the connecting structure 306 is coupled to the second channel structures 110b through the conductive contacts 128. Therefore, the first channel structures 110a and the second channel structures 110b are coupled together to form an integrated channel structure 133. One or more integrated channel structure 133 form a memory string.

In some implementations, the second region 144 of the connecting structures 306 is connected to a conductive line 130. A thickness of the second region 144 can be equal to or larger than a thickness of the conductive line 130. The thickness can be a dimension along Y direction. In some implementations, the second region 144 is at least 50 nm thicker than the conductive line 130. In some implementations, the thickness of the second region 144 is between 100 nm and 350 nm, and the thickness for the conductive line 130 is between 50 nm and 300 nm. Thicker second region 144 can reduce interference or leakage between the conductive line 130 and other two regions.

As noted above, the conductive line 130 can be used to control the flow of current between the first region 142 (e.g., collector) and the third region 318 (e.g., emitter). The control can be achieved through the modulation of the conductivity of the second region 144 (e.g., base). When an electrical signal is applied to the second region 144 (e.g., base), the current flowing through the second channel structures 110b can be substantially similar to or larger than the current flowing through the first channel structures 110a. This addresses the issue of degraded current in the channel structures in a multi-stacked 3D memory device, maintaining uniform current distribution across the integrated channel structures 133, and enhancing consistent device performance and reliability throughout the entire semiconductor device 300.

Although not shown, it is understood that the connecting structure 306 of the first semiconductor structure 302 can include the first region 142 with the first conductive type, while the channel plug 323 in the second channel structure 110b can include the second region 144 with the second conductive type and the third region 318 with the first conductive type. The first region 142, the second region 144 and the third region 318 are connected through a bonding process of the first semiconductor structure 302 and the second semiconductor structure 304. The combined three regions can form a bipolar junction for current amplification.

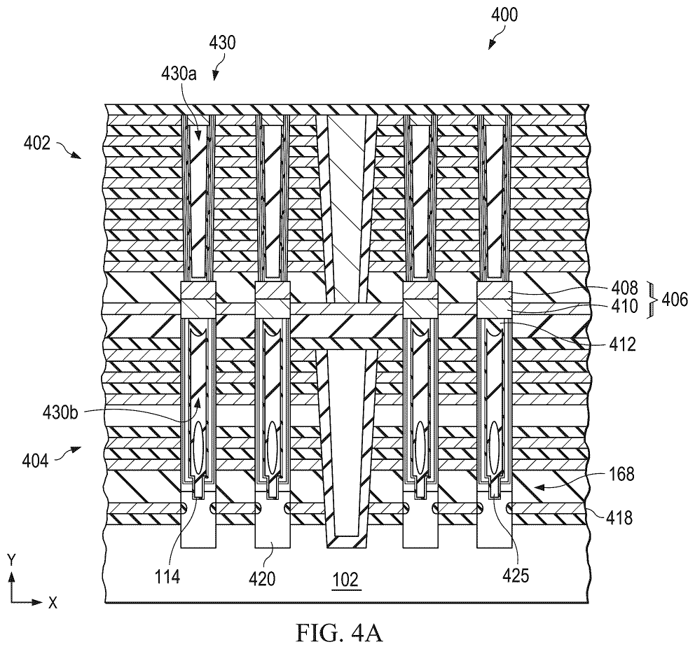

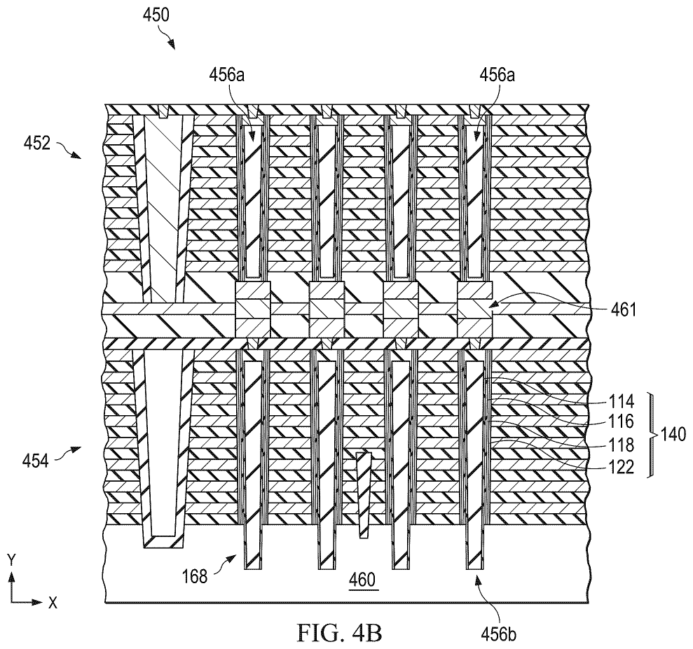

FIGS. 4A and 4B illustrate cross-section views of example semiconductor devices with different pick-up structures for source terminals of memory strings. Specifically, FIG. 4A illustrates a cross-section view of an example semiconductor device 400 with semiconductor plugs. The semiconductor device 400 includes a first semiconductor structure 402 and a second semiconductor structure 404. The first semiconductor structure 402 includes multiple first channel structures 430a extending along a first direction, e.g., Y direction, and multiple connecting structures 406. Each connecting structure 406 can include a first region 408 of a first conductive type and a second region 410 of a second conductive type. The second semiconductor structure 404 can include multiple second channel structures 430b extending along the Y direction. Each second channel structure 430b includes a third region 412 of the first conductive type. The first semiconductor structure 402 and the second semiconductor structure 404 are bonded together to couple the first channel structures 430a and the corresponding second channel structures 430b to form integrated channel structures 430.

As illustrated, at the second end 168 of each second channel structure 430b, a semiconductor plug 420 is formed. The semiconductor plugs 420 can extend partially into the semiconductor substrate 102. The semiconductor plugs 420 are in contact with the semiconductor channel layer 114 of the second channel structures 430b through a semiconductor contact 425. The semiconductor contacts 425 can include dielectric material surrounded by the semiconductor channel layer 114. The semiconductor contact 425 can have a narrower lateral dimension, e.g., along X direction, compared to that of the second channel structures 430b.

The semiconductor plugs 420 can be formed through a selective epitaxial growth (SEG) process, in which the semiconductor plugs 420 are epitaxially grown from a substrate 102. It is understood that in some implementations, the semiconductor plugs 420 include single crystalline silicon that is part of substrate 102. A semiconductor plug 420 formed through the SEG process is also referred to as an SEG plug. The semiconductor plugs 420 can function as a channel controlled by a source select gate 418 of memory strings.

In some implementations, the lateral dimension of the upper and lower surface of semiconductor plugs 420 can be substantially the same along the horizontal direction (the X-direction). In some implementations, the lateral dimension of semiconductor plugs 420 along the horizontal direction (the X-direction) is substantially the same as the width of the second channel structures 430b, as illustrated in FIG. 4A.

Although not shown, it is understood that a structure similar to or same as the semiconductor plugs 420 or SEG plugs can be formed in the semiconductor devices 100 and 300.

FIG. 4B illustrates a cross-section view of an example semiconductor device 450 with a substrate layer 460 as source terminals pickup. The semiconductor device 450 includes a first semiconductor structure 452 and a second semiconductor structure 454. The connecting structure 461 can be fabricated at the first end of the first channel structures 456a. The connecting structure 461 can be implemented as the connecting structure 150 in FIG. 1. The second semiconductor structure 454 includes multiple second channel structures 456b extending along the Y direction. In the semiconductor device 450, the silicon substrate is thinned. The substrate can be thinned by grinding, wet/dry etching, chemical mechanical polishing (CMP), or any combination thereof. In some implementations, the layered structure 140 is partially removed at the second end 168 of the second channel structures 456b. More specially, the blocking layer 122, the charge trapping layer 118 and the dielectric layer 116 are removed at the second end 168 of the second channel structure 456b, exposing the semiconductor channel layer 114.

A substrate layer 460, e.g., silicon, can be deposited in contact with the exposed semiconductor channel layer 114. Thus, the semiconductor channel layer 114 is electrically connected to the substrate layer 460. The substrate layer 460 can be utilized as the source line for the integrated channel structure 456, e.g., the integrated first channel structures 456a and second channel structures 456b. The source line can control the voltage applied to the memory strings during programming, reading, and/or erasing operations.

Although not shown, it is understood that a structure similar to or same as the substrate layer 460 can be formed in the semiconductor devices 100 and 300.

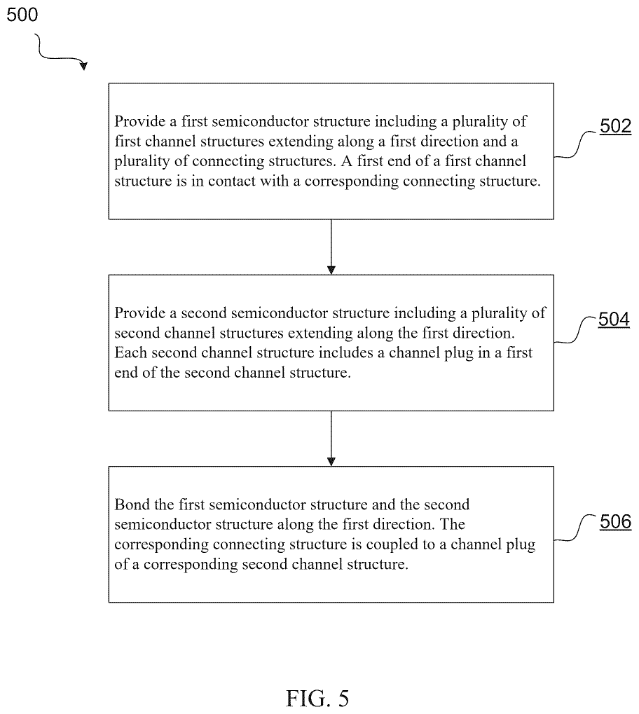

FIG. 5 illustrates a flow chart of an example process 500 to form an example semiconductor device. At step 502, a first semiconductor structure is provided. The first semiconductor structure includes a plurality of first channel structures extending along a first direction and a plurality of connecting structures. A first end of a first channel structure is in contact with a corresponding connecting structure. The first semiconductor structure can be, e.g., the first semiconductor structure 104 of FIGS. 1-2J, the first semiconductor structure 302 of FIG. 3, the first semiconductor structure 402 of FIG. 4A or the first semiconductor structure 452 of FIG. 4B. The first channel structures can be, e.g., the first channel structures 110a of FIGS. 1-3, the first channel structures 430a of FIG. 4A, or the first channel structures 456a of FIG. 4B. The connecting structures can be, e.g., the connecting structures 150 of FIGS. 1-2J, the connecting structures 306 of FIG. 3, the connecting structures 406 of FIG. 4A, or the connecting structures 461 of FIG. 4B.

At step 504, a second semiconductor structure is provided. The second semiconductor structure includes a plurality of second channel structures extending along the first direction. Each second channel structure includes a channel plug in a first end of the second channel structure. The second semiconductor structure can be, e.g., the second semiconductor structure 105 of FIGS. 1-2J, the second semiconductor structure 304 of FIG. 3, the second semiconductor structure 404 of FIG. 4A or the second semiconductor structure 454 of FIG. 4B. The second channel structures can be, e.g., the second channel structures 110b of FIGS. 1-3, the second channel structures 430b of FIG. 4A, or the second channel structures 456b of FIG. 4B. The channel plug can be, e.g., the channel plug 217 of FIG. 2I, or the channel plug 323 of FIG. 3.

At step 506, the first semiconductor structure and the second semiconductor structure are bonded. The corresponding connecting structure is coupled to a channel plug of a corresponding second channel structure.

In some implementations, the connecting structure includes a first region of a first conductive type and a second region of a second conductive type. The channel plug of the corresponding second channel structure includes a third region of the first conductive type. The first region can be, e.g., the first region 142 of FIGS. 1-3 and 4B, or the first region 408 of FIG. 4A. The second region can be, e.g., the second region 144 of FIGS. 1-3 and 4B, or the second region 410 of FIG. 4A. The third region can be, e.g., the third region 146 of FIGS. 1-2J and 4B, the third region 318 of FIG. 3, or the third region 412 of FIG. 4A.

In some implementations, the connecting structure comprises a first region of a first conductive type, a second region of a second conductive type, and a third region of the first conductive type, as illustrated in FIGS. 1 and 4B. In some implementations, the first conductive type is N conductive type, and the second conductive type is P conductive type.

In some implementations, the method further includes forming a plurality of conductive contacts on the second semiconductor structure. A first end of a conductive contact is coupled to the corresponding connecting structure. A second end of the conductive contact is coupled to the channel plug of the corresponding second channel structure. The first end is opposite to the second end along the first direction. The conductive contacts can be, e.g., the conductive contacts 128 of FIGS. 1 and 2E-4B. The first direction can be, e.g., the Y direction of FIGS. 1-4B.

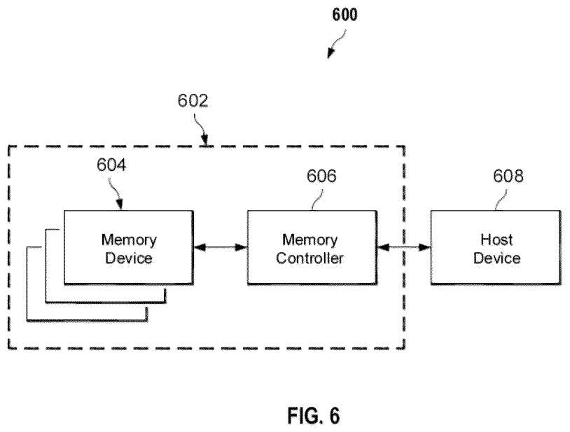

FIG. 6 illustrates a block diagram of a system 600 having one or more semiconductor devices (e.g., memory devices), according to one or more implementations of the present disclosure. The system 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 6, the system 600 can include a host device 608 and a memory system 602 having one or more 3D memory devices 604 and a memory controller 606. Host device 608 can include a processor of an electronic device, such as a central processing unit (CPU), or a system-on-chip (SoC), such as an application processor (AP). Host device 608 can be configured to send or receive data to or from the one or more 3D memory devices 604.

A 3D memory device 604 can be any 3D memory device disclosed herein, such as the semiconductor device 100 of FIG. 1, or a part of the semiconductor device 100 of FIGS. 1-2J, or a structure at an intermediate fabrication process of the semiconductor device 100 of FIGS. 1-2J, or a semiconductor device 300 of FIG. 3, or semiconductor device 400 of FIG. 4A, or the semiconductor device 450 of FIG. 4B.

In some implementations, a 3D memory device 604 includes a NAND Flash memory. Memory controller 606 (a.k.a., a controller circuit) is coupled to 3D memory device 604 and host device 608. Consistent with implementations of the present disclosure, 3D memory device 604 can include a plurality of conductive interconnections through a cover layer that are in contact with conductive pads in a conductive pad layer, and memory controller 606 can be coupled to 3D memory device 604 through at least one of the plurality of conductive interconnections. Memory controller 606 is configured to control 3D memory device 604. For example, memory controller 606 may be configured to operate a plurality of channel structures 110 via gate lines 136. Memory controller 606 can manage data stored in 3D memory device 604 and communicate with host device 608.

In some implementations, memory controller 606 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 606 can be configured to control operations of 3D memory device 604, such as read, erase, and program (or write) operations. Memory controller 606 can also be configured to manage various functions with respect to the data stored or to be stored in 3D memory device 604 including, but not limited to bad-block management, garbage collection, logical-to-physical address conversion, wear leveling, etc. In some implementations, memory controller 606 is further configured to process error correction codes (ECCs) with respect to the data read from or written to 3D memory device 604. Any other suitable functions may be performed by memory controller 606 as well, for example, formatting 3D memory device 604.

Memory controller 606 can communicate with an external device (e.g., host device 608) according to a particular communication protocol. For example, memory controller 606 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 606 and one or more 3D memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 6, memory controller 606 and a single 3D memory device 604 may be integrated into a memory card 602. Memory card 602 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layer 116s.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” e.g., NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a first semiconductor structure comprising a plurality of first channel structures extending along a first direction and a plurality of connecting structures, each of the plurality of connecting structures comprising a first region of a first conductive type, a second region of a second conductive type, and a third region of the first conductive type, a first end of a first channel structure of the plurality of first channel structures being in contact with the first region of a corresponding connecting structure of the plurality of connecting structures; and
a second semiconductor structure comprising a plurality of second channel structures extending along the first direction,
wherein the first semiconductor structure and the second semiconductor structure are bonded along the first direction, and wherein the corresponding connecting structure is coupled to a first end of a corresponding second channel structure of the plurality of second channel structures.

2. The semiconductor device of claim 1, wherein the first conductive type is N conductive type, and the second conductive type is P conductive type.

3. The semiconductor device of claim 1,
wherein the first semiconductor structure comprises a first conductive line coupled to a second end of the first channel structure, the second end of the first channel structure being opposite to the first end of the first channel structure along the first direction, and
wherein the second semiconductor structure comprises a second conductive line coupled to a second end of the corresponding second channel structure, the first end of the corresponding second channel structure being opposite to the second end of the corresponding second channel structure along the first direction.

4. The semiconductor device of claim 1, wherein the first semiconductor structure further comprises a plurality of conductive structures, a conductive structure of the plurality of conductive structures being in contact with the first region or the third region of the corresponding connecting structure.

5. The semiconductor device of claim 1, wherein the second semiconductor structure comprises a plurality of conductive contacts isolated by a dielectric material, a first end of a conductive contact of the plurality of conductive contacts being coupled to the third region of the corresponding connecting structure, a second end of the conductive contact of the plurality of conductive contacts being coupled to the corresponding second channel structure of the plurality of second channel structures, the first end being opposite to the second end along the first direction.

6. The semiconductor device of claim 1, wherein the second region of the corresponding connecting structure is connected to a conductive line, and a thickness of the second region of the corresponding connecting structure is equal to or larger than a thickness of the conductive line.

7. The semiconductor device of claim 6, wherein the thickness of the second region is a dimension of the second region along the first direction, and the thickness of the conductive line is a dimension of the conductive line along the first direction.

8. The semiconductor device of claim 1, wherein each of the plurality of second channel structures comprises a channel plug.

9. A semiconductor device, comprising:
a first semiconductor structure comprising a plurality of first channel structures extending along a first direction and a plurality of connecting structures, each of the plurality of connecting structures comprising a first region of a first conductive type and a second region of a second conductive type, a first end of a first channel structure of the plurality of first channel structures being in contact with the first region of a corresponding connecting structure of the plurality of connecting structures; and
a second semiconductor structure comprising a plurality of second channel structures extending along the first direction, each of the plurality of second channel structures comprising a channel plug in a first end of the second channel structure, the channel plug comprising a third region of the first conductive type,
wherein the first semiconductor structure and the second semiconductor structure are bonded along the first direction, and wherein the corresponding connecting structure is coupled to a channel plug of a corresponding second channel structure of the plurality of second channel structures.

10. The semiconductor device of claim 9, wherein the first conductive type is N conductive type, and the second conductive type is P conductive type.

11. The semiconductor device of claim 9,
wherein the first semiconductor structure comprises a first conductive line coupled to a second end of the first channel structure, the first end of the first channel structure being opposite to the second end of the first channel structure along the first direction, and
wherein the second semiconductor structure comprises a second conductive line coupled to a second end of the corresponding second channel structure, the first end of the corresponding second channel structure being opposite to the second end of the corresponding second channel structure.

12. The semiconductor device of claim 9, wherein the first semiconductor structure further comprises a plurality of conductive structures, a conductive structure of the plurality of conductive structures being in contact with the second region of the corresponding connecting structure.

13. The semiconductor device of claim 9, wherein the second semiconductor structure comprises a plurality of conductive contacts isolated by a dielectric material, a first end of a conductive contact of the plurality of conductive contacts being coupled to the second region of the corresponding connecting structure, a second end of the conductive contact being coupled to the channel plug of the corresponding second channel structure, the first end being opposite to the second end along the first direction.

14. The semiconductor device of claim 9, wherein the second region of the corresponding connecting structure is connected to a conductive line, and a thickness of the second region of the corresponding connecting structure is equal to or larger than a thickness of the conductive line.

15. The semiconductor device of claim 14, wherein the thickness of the second region is a dimension of the second region along the first direction, and the thickness of the conductive line is a dimension of the conductive line along the first direction.

16. A method for forming a semiconductor device, comprising:
providing a first semiconductor structure comprising a plurality of first channel structures extending along a first direction and a plurality of connecting structures, a first end of a first channel structure of the plurality of first channel structures being in contact with a corresponding connecting structure of the plurality of connecting structures;
providing a second semiconductor structure comprising a plurality of second channel structures extending along the first direction, each of the plurality of second channel structures comprising a channel plug in a first end of the second channel structure; and
bonding the first semiconductor structure and the second semiconductor structure, wherein the corresponding connecting structure is coupled to a channel plug of a corresponding second channel structure of the plurality of second channel structures.

17. The method of claim 16, wherein the corresponding connecting structure comprises a first region of a first conductive type and a second region of a second conductive type, and wherein the channel plug of the corresponding second channel structure comprises a third region of the first conductive type.

18. The method of claim 16, wherein the corresponding connecting structure comprises a first region of a first conductive type, a second region of a second conductive type, and a third region of the first conductive type.

19. The method of claim 17, wherein the first conductive type is N conductive type, and the second conductive type is P conductive type.

20. The method of claim 16, the method further comprising forming a plurality of conductive contacts on the second semiconductor structure, a first end of a conductive contact of the plurality of conductive contacts being coupled to the corresponding connecting structure of the plurality of connecting structures, a second end of the conductive contact of the plurality of conductive contacts being coupled to the channel plug of the corresponding second channel structure of the plurality of second channel structures, the first end being opposite to the second end along the first direction.
